(19) United States
(12) Patent Application Publication
(10) Pub. No.: US 2025/0183111 A1
(43) Pub. Date: Jun. 5, 2025

(54) POWER-ELECTRONICS PACKAGING, INTERFACE AND CONFIGURATION

(71) Applicant: Joby Aero, Inc., Santa Cruz, CA (US)

(72) Inventors: Robert Ramm, Woodside, CA (US); Joseph Milia, Palo Alto, CA (US)

(21) Appl. No.: 18/960,116

(22) Filed: Nov. 26, 2024

Related U.S. Application Data
(60) Provisional application No. 63/604,325, filed on Nov. 30, 2023.

(51) Int. Cl. H01L 23/34; B64C 27/26; B64C 27/28; B64C 29/00; B64F 5/10; H01L 23/00; H01L 23/495; H02M 7/5387

(52) U.S. Cl. CPC H01L 23/34; H01L 23/49575; H01L 24/13; H01L 24/81; H02M 7/5387; B64C 27/26; B64C 27/28; B64C 29/0033; B64F 5/10; H01L 2224/13099; H01L 2224/8184

(57) ABSTRACT

A half-bridge package for a power inverter comprises a first switch and a first lead coupled to the first switch, and a second switch and a second lead coupled to the second switch, wherein the first lead and the second lead are adjacent to one another. At least one of the first switch and the second switch are formed on a die, and the half-bridge package may further comprise a thermistor mounted to the die. In some examples the thermistor is sintered to the die.

### RELATED APPLICATION DATA

This application claims the benefit of U.S. Application Ser. No. 63/604,325 filed Nov. 30, 2023, the contents of which are incorporated herein by reference as if explicitly set forth.

### TECHNICAL FIELD

This invention relates generally to power-electronics, including the lead frame configuration and packaging of a half-bridge module in an inverter.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a plan view of an aircraft according to some examples.

FIG. 2 is a schematic view of an aircraft energy system for use in the aircraft of FIG. 1, according to some examples.

FIG. 3 is a schematic view of an electrical system power architecture for a six motor, six battery aircraft according to some examples.

FIG. 4A is a perspective view of the aircraft in a vertical thrust configuration, according to some examples.

FIG. 4B is a perspective view of the aircraft in a horizontal thrust configuration, according to some examples.

FIG. 5A, FIG. 5B and FIG. 5C illustrate the tilting of an aircraft propulsion system and related components such as a propeller and nacelle according to some examples.

FIG. 6A, FIG. 6B and FIG. 6C illustrate the tilting of an aircraft propulsion system and related components such as a propeller and nacelle according to some examples.

FIG. 7 is a circuit diagram of a power inverter and its load, according to some examples.

FIG. 8 is perspective view of a half-bridge package for use in the power inverter of FIG. 7, according to some examples.

FIG. 9 is perspective view of a lead frame and associated components of the half-bridge package of FIG. 8, according to some examples.

FIG. 10 is perspective view of a lead frame and associated components of the half-bridge package of FIG. 8 with the power-negative lead removed, according to some examples.

FIG. 11 is perspective view of a lead frame and associated components of the half-bridge package of FIG. 8 with the power-negative lead removed, according to some examples.

FIG. 12 is a perspective showing the location and mounting of the thermistor for each switch of the half-bridge package of FIG. 8 and FIG. 9.

### DETAILED DESCRIPTION

The following description of some examples of the invention is not intended to limit the invention to these examples, but rather to enable any person skilled in the art to make and use this invention.

Disclosed herein is a package and lead frame for use in a DC-AC power inverter in an aircraft 100. A half-bridge circuit is provided in a single package, in which the leads in the package connecting each side of the half-bridge to the DC power source are adjacent to each other and generally parallel. This reduces the area circumscribed by the leads and reduces the inductance of the half-bridge, which improves the performance of an inverter including such half-bridges. An inverter including such half-bridges finds particular application in electrically-powered aircraft, in which the DC power source is a battery, a fuel cell or a hybrid of the two.

Cost is a particular driver for the design of conventional DC-AC power inverters, such as for electric vehicles for example. In the aviation context, other considerations mitigate or take precedence over the cost of the power inverter. In some examples described herein, the added cost and complexity of making the disclosed package and lead frame is justified, since the resulting package takes up less space in an aircraft, resulting in more efficient overall packaging of aircraft components, weighs less, resulting in improved payload capacity, and is more efficient, resulting in increased range. Additionally, a more efficient power inverter will generate less heat, which will require a cooling system of lower capacity.

Such benefits are often reaped cumulatively through efforts to make aircraft components smaller, lighter and more efficient, even though an individual component itself may not make a noticeable difference. Finally, as will be described in more detail below, the aircraft 100 includes multiple power inverters for redundancy. The savings in mass, space and efficiency are thus multiplied compared to other uses, in which a single power inverter may be used.

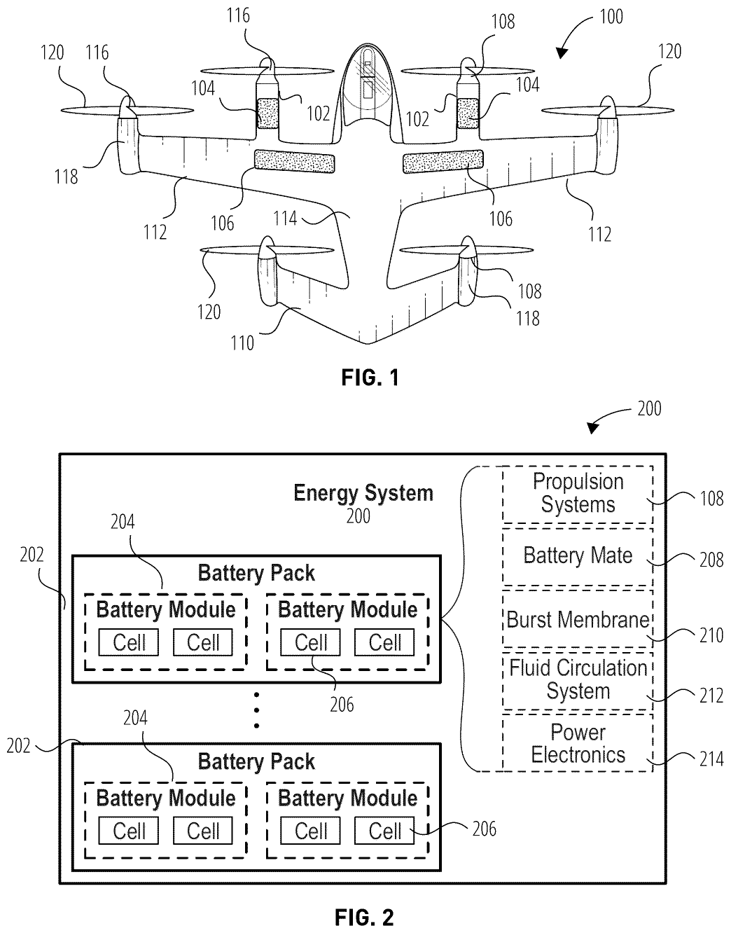

FIG. 1 is a plan view of an aircraft 100. The aircraft 100 includes a fuselage 114, two wings 112, an empennage 110 and propulsion systems 108 embodied as tiltable rotor assemblies 116 located in nacelles 118. The aircraft 100 includes one or more power sources embodied in FIG. 1 as nacelle battery packs 104 and wing battery packs 106. In the illustrated example, the nacelle battery packs 104 are located in inboard nacelles 102, but of course it will be appreciated that the nacelle battery packs 104 could be located in other nacelles 118 forming part of the aircraft 100. The battery packs form part of the energy system 200 described with reference to FIG. 2. The aircraft 100 will typically include associated equipment such as an electronic infrastructure, control surfaces, a cooling system, landing gear and so forth.

The wings 112 function to generate lift to support the aircraft 100 during forward flight. The wings 112 can additionally or alternately function to structurally support the battery packs 202, battery module 204 and/or propulsion systems 108 under the influence of various structural stresses (e.g., aerodynamic forces, gravitational forces, propulsive forces, external point loads, distributed loads, and/or body forces, etc.). The wings 112 can have any suitable geometry and/or arrangement on the aircraft.

FIG. 2 is a schematic view of an aircraft energy system 200 for use in the aircraft 100 of FIG. 1, according to some examples. As shown, the energy system 200 includes one or more battery packs 202. Each battery pack 202 may include one or more battery modules 204, which in turn may comprise a number of cells 206.

Typically associated with a battery pack 202 are one or more electric propulsion systems 108, a battery mate 208 for connecting it to other components in energy system 200, a burst membrane 210 as part of a venting system, a fluid circulation system 212 for cooling, and power electronics 214 for regulating delivery of electrical power (from the battery during operation and to the battery during charging) and to provide integration of the battery pack 202 with the electronic infrastructure of the energy system 200. As shown in FIG. 1, the propulsion systems 108 may comprise a plurality of rotor assemblies.

The electronic infrastructure and the power electronics 214 can additionally or alternately function to integrate the battery packs 202 into the energy system of the aircraft.

The electronic infrastructure can include a Battery Management System (BMS), power electronics (HV architecture, power components, etc.), LV architecture (e.g., vehicle wire harness, data connections, etc.), and/or any other suitable components. The electronic infrastructure can include inter-module electrical connections, which can transmit power and/or data between battery packs and/or modules. Inter-modules can include bulkhead connections, bus bars, wire harnessing, and/or any other suitable components.

The battery packs 202 function to store electrochemical energy in a rechargeable manner for supply to the propulsion systems 108. Battery packs 202 can be arranged and/or distributed about the aircraft in any suitable manner. Battery packs can be arranged within wings (e.g., inside of an airfoil cavity), inside nacelles, and/or in any other suitable location on the aircraft. In a specific example, the system includes a first battery pack within an inboard portion of a left wing and a second battery pack within an inboard portion of a right wing. In a second specific example, the system includes a first battery pack within an inboard nacelle of a left wing and a second battery pack within an inboard nacelle of a right wing. Battery packs 202 may include a plurality of battery modules 204.

The energy system 200 includes a cooling system (e.g. fluid circulation system 212) that functions to circulate a working fluid within the battery pack 202 to remove heat generated by the battery pack 202 during operation or charging. Battery cells 206, battery module 204 and/or battery packs 202 can be fluidly connected by the cooling system in series and/or parallel in any suitable manner.

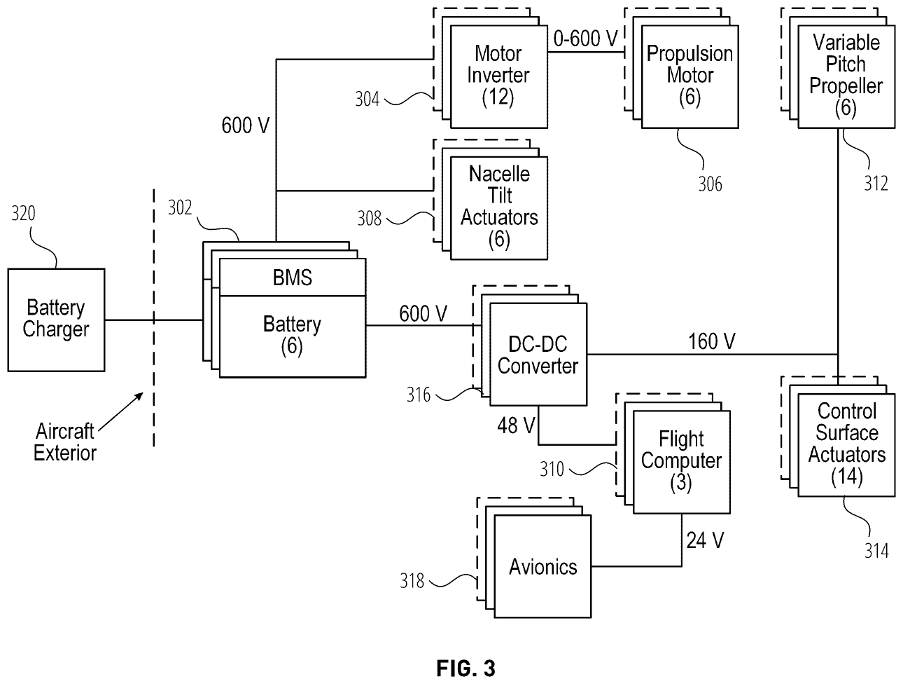

FIG. 3 is a schematic view of an electrical system power architecture for a six motor, six battery aircraft 100 according to some examples. Each of the six batteries 302 supplies two power inverters 304, for a total of 12 power inverters 304. The nominal voltage of the batteries is 600V. Each of the six propulsion motors 306 has two sets of windings, with each motor powered by two inverters, one for each set of windings. The two power inverters 304 powering a single motor are each supplied power by different batteries. In addition to supplying power to the power inverters 304, the batteries 302 also supply power to the rotor deployment mechanisms 308 (nacelle tilt actuators), which are used to position the variable pitch propellers 312 during various flight modes (vertical take-off and landing configuration, forward flight configuration, and transitions therebetween).

A flight computer 310 monitors the current from each of the twelve motor power inverters 304 that are supplying power to the twelve winding sets in the six propulsion motors 306. The flight computer 310 may also control the motor current supplied to each of the 12 sets of windings of the six propulsion motors 306. The batteries 302 also supply power to the blade pitch motors and position encoders of the variable pitch propellers 312. The batteries 302 also supply power to control surface actuators 314 used to position various control surfaces on the aircraft 100. The blade pitch motors and the control surface actuators 314 may receive power run through a DC-DC converter 316, stepping the voltage down from 600V to 160V, for example. A suite of avionics 318 is also be coupled to the flight computer. A battery charger 320 is used to recharge the batteries 302, and the battery charger are typically external to the aircraft and ground-based.

The use of redundant power inverters 304, redundant windings in the propulsion motors 306, and the available supply of power from different batteries or other power sources, provides additional safety.

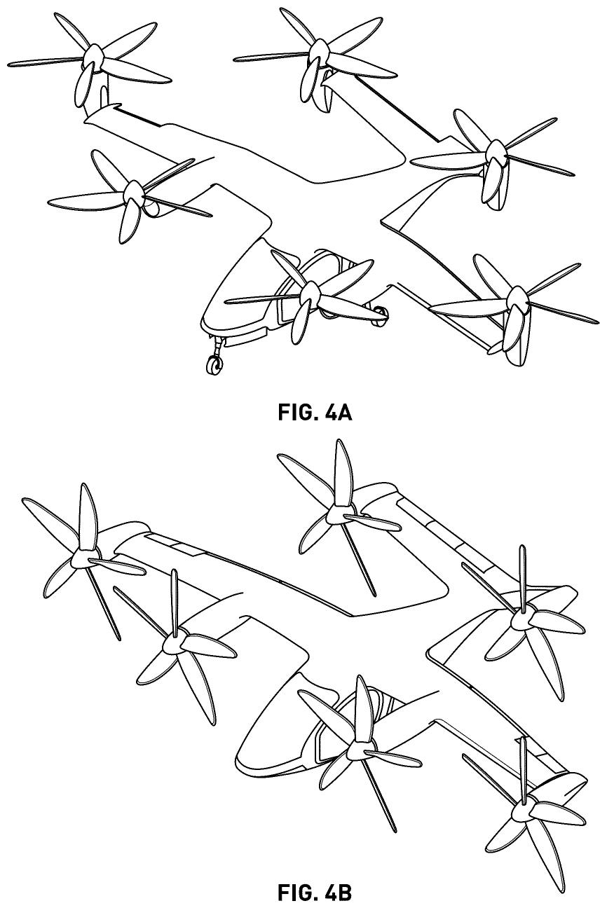

FIG. 4A is a perspective view of the aircraft 100 in a vertical thrust configuration, according to some examples. The aircraft 100 has fixed wings 112, which may be forward swept wings, with propulsion systems 108 of the same or different types adapted for both vertical take-off and landing and for forward flight. As illustrated in FIG. 4A, in a vertical take-off configuration the propulsion systems 108 are positioned or configured for vertical thrusting. The propulsion systems 108 along the wings include electric propulsion motors 306 and rotors 120 that are adapted to articulate from a forward flight configuration to a vertical flight configuration using deployment mechanisms that may reside in the nacelle 118, and that deploy the motor and rotor 120 while all or most of the nacelle remains in place attached to the wing. In some aspects, the propeller blades may stow and nest into the nacelle body. The motor driven propulsion systems 108 at the wing tips may deploy from a forward flight configuration to a vertical take-off and landing configuration along a pivot axis wherein the nacelle 118 and the electric motor and rotor 120 deploy in unison. Although illustrated with one mid-span propulsion system 108 and one wingtip propulsion system 108, in some aspects more mid-span propulsion assemblies may be present.

The aircraft fuselage 114 extends rearward and is attached to empennage 110. The empennage 110 has rear propulsion systems 108 attached thereto. The motor driven propulsion systems 108 at the tips of the empennage 110 also deploy from a forward flight configuration to a vertical take-off and landing configuration along a pivot axis, wherein the nacelle and the electric motor and propeller deploy in unison.

FIG. 4B is a perspective view of the aircraft 100 in a horizontal thrust configuration, according to some examples. In this forward flight configuration, the propulsion systems 108 are positioned or configured to provide forward thrust during horizontal flight.

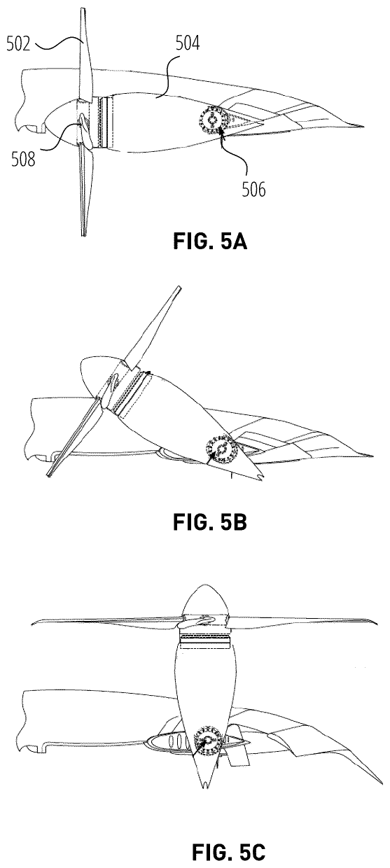

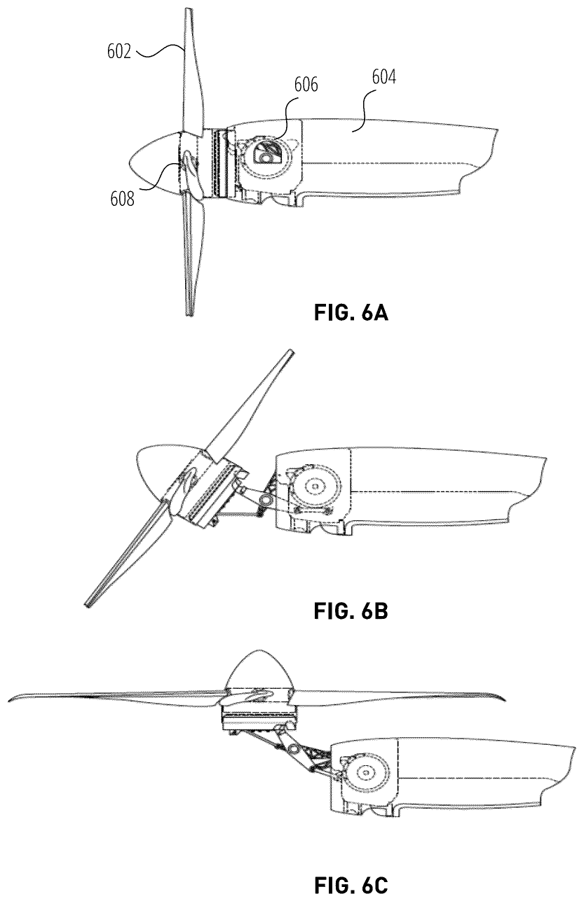

FIG. 5A, FIG. 5B and FIG. 5C illustrate the tilting of the propulsion systems 108 and related components such as the rotor 502 and nacelle 504 according to some examples. The aircraft is preferably an eVTOL airplane (e.g., a multi-modal aircraft) as illustrated, but can additionally or alternatively include any suitable aircraft. The aircraft 100 is preferably a tiltrotor aircraft with a plurality of aircraft propulsion systems that are operable between a forward arrangement (FIG. 5A, and FIG. 6A) and a hover or vertical flight arrangement (FIG. 5C and FIG. 6C). However, the aircraft can alternatively be a fixed wing aircraft with one or more rotor assemblies or propulsion systems, a helicopter with one or more rotor assemblies (e.g., wherein at least one rotor assembly or aircraft propulsion system is oriented substantially axially to provide horizontal thrust), a tiltwing aircraft, a wingless aircraft (e.g., a helicopter, multi-copter, quadcopter), and/or any other suitable rotorcraft or vehicle propelled by propellers or rotors.

As shown in FIG. 5A to FIG. 5C, in one example a nacelle 504 including the aircraft propulsion systems 108 (including a motor, two power inverters and a radiator) and a rotor 502 with a blade-pitching mechanism 508 are tilted relative to the rest of the aircraft 100 by a tilt mechanism 506 located towards the rear of the nacelle 504.

When integrated into a propulsion tilt mechanism in an aircraft configurable between a forward configuration and a hover configuration, cooling subsystems can advantageously utilize an increase in available airflow in a hover configuration as discussed below.

FIG. 6A, FIG. 6B and FIG. 6C illustrate the tilting of the propulsion systems 108 and related components such as the rotor 502 relative to a nacelle 604 according to some examples. As can be seen in FIG. 6B and FIG. 6C, in this example the aircraft propulsion system propulsion systems 108 (including a motor, two inverters and radiator) and a rotor 602 with a blade-pitching mechanism 608 are tilted relative to the nacelle 604 by a tilt mechanism 606 located towards the front of the nacelle 604.

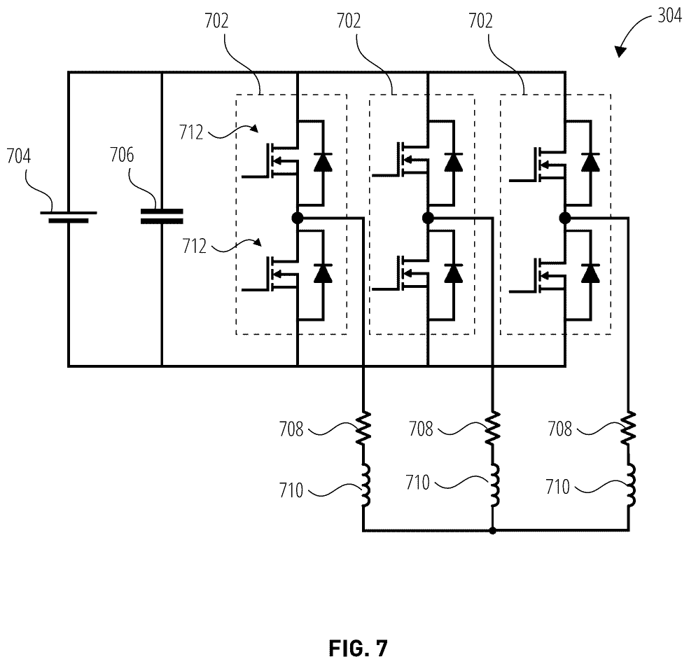

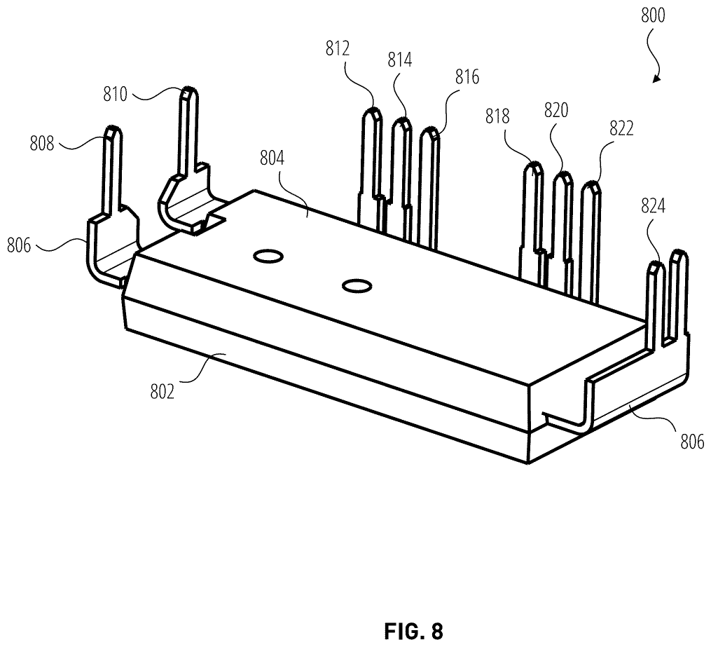

FIG. 7 is a circuit diagram of a three-phase power inverter 304 and its loads for use in the aircraft 100, according to some examples. The power inverter 304 comprises three interconnected half-bridge modules 702 coupled in parallel with a DC power source 704 such as a battery, and a capacitor 706. Each half-bridge module 702 is in turn coupled to a load, represented in FIG. 7 as a resistance 708 and an inductance 710. In some examples, the loads are the three phases of a three-phase motor.

Each half-bridge module 702 comprises two switches 712 connected in series as shown. In use, the switches 712 are selectively enabled and disabled to provide a phase-offset AC output to each of the attached loads. In some examples, the switches 712 are MOSFETs.

Each loop of the circuit comprising a single half-bridge module 702 and the DC power source 704 and its associated electrical connections, has an inherent inductance associated therewith. The functioning of the power inverter 304 can be improved by reducing this inherent inductance.

FIG. 8 is perspective view of a half-bridge package 800 for use in the power inverter 304 of FIG. 3, and FIG. 7, according to some examples. The half-bridge package 800 includes a substrate 802, an overmold 804, and a lead frame 806. The lead frame 806 includes a number of leads, including a power positive lead 808, a power negative lead 810, a high side Kelvin source lead 812, a high side gate lead 814, a high side thermistor lead 816, a low side Kelvin source lead 818, a low side gate lead 820, a low side thermistor lead 822 and half-bridge center lead 824. The leads are connected to components inside the half-bridge package 800 as discussed below.

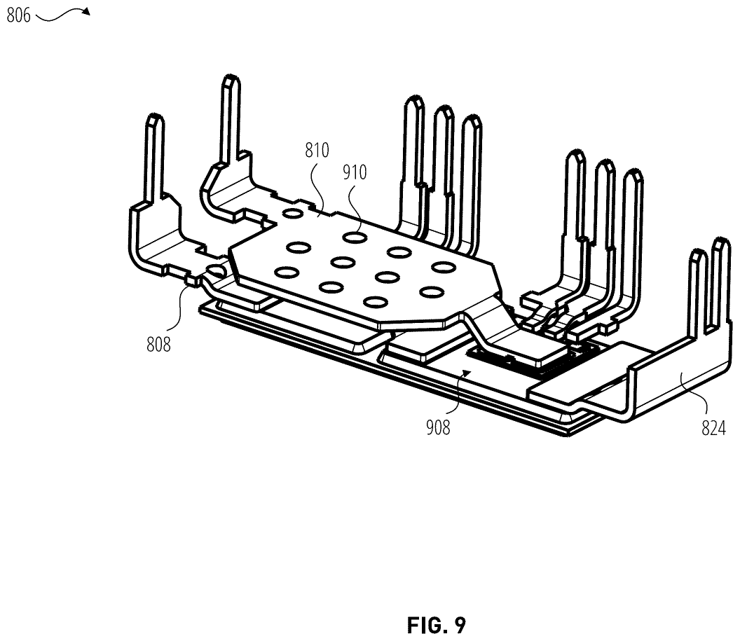

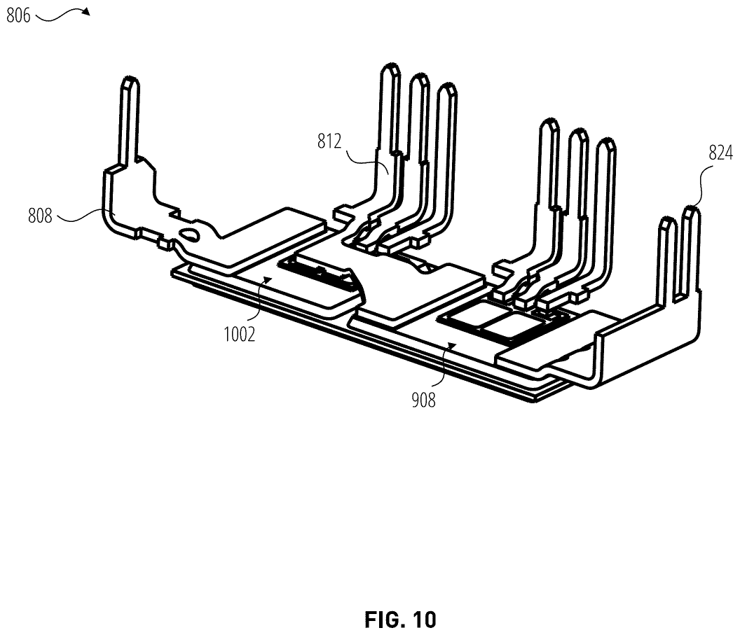

FIG. 9 is a perspective view of the lead frame 806 and associated components of the half-bridge package of FIG. 8, according to some examples. In FIG. 9, the substrate 802 and overmold 804 have been removed to illustrate the internal structure of the half-bridge package 800.

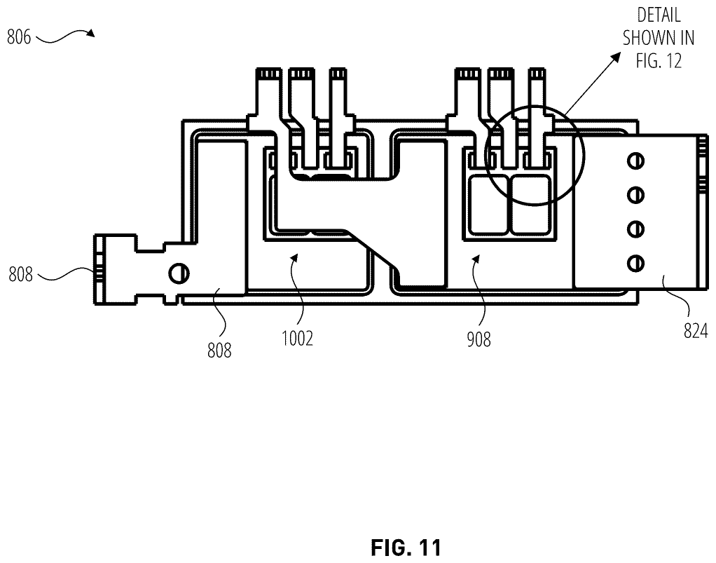

As can be seen in the figure, the power negative lead 810 is electrically connected to a first switch 908, while the power positive lead 808 is coupled to a second switch 1002 (see FIG. 10). located below and adjacent to the power negative lead 810. The center of the half-bridge module 702 formed by the first switch 908 and the second switch 1002 is coupled to a load via the half-bridge center lead 824. The power negative lead 810 is provided with holes 910 to facilitate the molding of the overmold 804.

The inductance of the loop of the circuit comprising the first switch 908, the second switch 1002 and the DC power source 704 is reduced by providing the two switches 908, 1002 next to each other in a single half-bridge package 800, and by overlapping the power positive lead 808 and the second switch 1002 with the power negative lead 810. This reduces the area circumscribed by these components and leads, with a corresponding reduction in the inductance of this loop.

FIG. 10 is a perspective view of a lead frame and associated components of the half-bridge package of FIG. 8 with the power negative lead 810 removed, according to some examples. FIG. 10 illustrates the location and configuration of the power positive lead 808 and the positions of the first switch 908 and the second switch 1002. Also shown is the high side Kelvin source lead 812 as well as the half-bridge center lead 824.

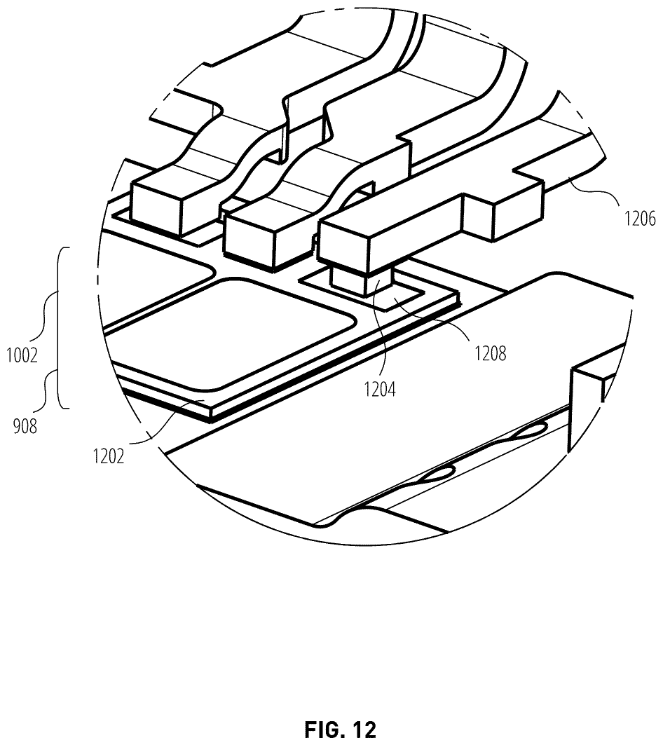

FIG. 11 is a plan view of the lead frame and associated components of the half-bridge package of FIG. 9, further illustrating the location and configuration of the power positive lead 808, and the positions of the first switch 908 and the second switch 1002. Also identified in FIG. 11 is the area shown in detail in FIG. 12.

FIG. 12 is a perspective showing the location and mounting of a thermistor 1204 for each switch 712 of the half-bridge package of FIG. 8 and FIG. 9. Accurately sensing of the temperature at a switch 712 in an inverter is difficult, and the actual temperature of a switch 712 can vary from the temperature measured at a more remote location used for temperature measurement in traditional inverters.

This problem is addressed in the current half-bridge package 800 by providing a thermistor 1204 directly on a die 1202 that includes the first switch 908. A similar arrangement is provided for the second switch 1002, which has its own thermistor.

The thermistor 1204 is connected directly to a pad 1208 on the die 1202, typically by sintering. A thermistor lead 1206 is connected to the thermistor 1204, by sintering, wire bonding or another technique. By providing the thermistor 1204 directly on the dies 1202 containing the switches 908, 1002, more accurate temperature measurements within the half-bridge package 800 are obtained.

Also provided is a method of manufacturing a half-bridge package, comprising coupling the first lead 810 to the first switch 908; and coupling the second lead 808 to the second switch 1002 such that the second lead 808 is adjacent to the first lead 810. In some examples, the first switch 908 and the second switch 1002 are located adjacent to each other in the half-bridge package, the first lead 810 passing over the second switch 1002. In some examples the method further comprise forming at least one of the first switch 908 and the second switch 1002 on a die 1202; and mounting a thermistor 1204 to the die 1202. Mounting the thermistor 1204 to the die 1202 can comprises sintering the thermistor to the die, and thermistor lead 1206 can be mounted onto the thermistor 1204.

Various examples are contemplated. Example 1 is a half-bridge package comprising: a first switch and a first lead coupled to the first switch; and a second switch and a second lead coupled to the second switch, wherein the first lead and the second lead are adjacent to one another.

In Example 2, the subject matter of Example 1 includes, wherein the first switch and the second switch are located adjacent to each other in the half-bridge package, the second lead passing over the first switch.

In Example 3, the subject matter of Examples 1-2 includes, wherein the first and second leads are inverter power leads.

In Example 4, the subject matter of Examples 1-3 includes, wherein at least one of the first switch and the second switch are formed on a die, the half-bridge package further comprising a thermistor mounted to the die.

In Example 5, the subject matter of Example 4 includes, wherein the thermistor is sintered to the die.

In Example 6, the subject matter of Examples 4-5 includes, a thermistor lead mounted to the thermistor.

In Example 7, the subject matter of Examples 5-6 includes, a thermistor lead mounted to the thermistor.

Example 8 is a power inverter comprising, a plurality of interconnected half-bridges, each half-bridge comprising: a first switch and a first lead coupled to the first switch; and a second switch and a second lead coupled to the second switch, wherein the first lead and the second lead are adjacent to one another.

In Example 9, the subject matter of Example 8 includes, wherein the first switch and the second switch in each half-bridge package are located adjacent to each other in each half-bridge package, the second lead passing over the first switch.

In Example 10, the subject matter of Examples 8-9 includes, wherein the first and second leads of each half-bridge package are inverter power leads.

In Example 11, the subject matter of Examples 8-10 includes, wherein at least one of the first switch and the second switch in each half-bridge package are formed on a die, each half-bridge package further comprising a thermistor mounted to the die.

In Example 12, the subject matter of Example 11 includes, wherein the thermistor in each half-bridge package is sintered to the die in that half-bridge package.

In Example 13, the subject matter of Example 12 includes, wherein each half-bridge package comprises a thermistor lead mounted to the thermistor in that half-bridge package.

In Example 14, the subject matter of Examples 11-13 includes, wherein each half-bridge package comprises a thermistor lead mounted to the thermistor in that half-bridge package.

Example 15 is a method of making a half-bridge package, comprising: coupling a first lead to a first switch; and coupling a second lead to a second switch such that the second lead is adjacent to the first lead.

In Example 16, the subject matter of Example 15 includes, wherein the first switch and the second switch are located adjacent to each other in the half-bridge package, the second lead passing over the first switch.

In Example 17, the subject matter of Examples 15-16 includes, forming at least one of the first switch and the second switch on a die; and mounting a thermistor to the die.

In Example 18, the subject matter of Example 17 includes, wherein mounting the thermistor to the die comprises sintering the thermistor to the die.

In Example 19, the subject matter of Examples 17-18 includes, mounting a thermistor lead onto the thermistor.

In Example 20, the subject matter of Examples 18-19 includes, mounting a thermistor lead onto the thermistor.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20. Example 23 is a system to implement of any of Examples 1-20. Example 24 is a method to implement of any of Examples 1-20.

Embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

The term “rotor” as utilized herein when referring to a thrust-generating element, can refer to a rotor, a propeller, and/or any other suitable rotary aerodynamic actuator. While a rotor can refer to a rotary aerodynamic actuator that makes use of an articulated or semi-rigid hub (e.g., wherein the connection of the blades to the hub can be articulated, flexible, rigid, and/or otherwise connected), and a propeller can refer to a rotary aerodynamic actuator that makes use of a rigid hub (e.g., wherein the connection of the blades to the hub can be articulated, flexible, rigid, and/or otherwise connected), no such distinction is explicit or implied when used herein, and the usage of “rotor” can refer to either configuration, and any other suitable configuration of articulated or rigid blades, and/or any other suitable configuration of blade connections to a central member or hub. Likewise, the usage of “propeller” can refer to either configuration, and any other suitable configuration of articulated or rigid blades, and/or any other suitable configuration of blade connections to a central member or hub. Accordingly, the tiltrotor aircraft can be referred to as a tilt-propeller aircraft, a tilt-prop aircraft, and/or otherwise suitably referred to or described.

The term “board” as utilized herein, in reference to the control board, inverter board, or otherwise, preferably refers to a circuit board. More preferably, “board” refers to a printed circuit board (PCB) and/or electronic components assembled thereon, which can collectively form a printed circuit board assembly (PCBA). In a first example, the control board is a PCBA. In a second example, each inverter board is a PCBA. However, “board” can additionally or alternatively refer to a single sided PCB, double sided PCB, multi-layer PCB, rigid PCB, flexible PCB, and/or can have any other suitable meaning.

The aircraft can include any suitable form of power storage or power storage unit (battery, flywheel, ultra-capacitor, battery, fuel tank, etc.) which powers the actuator(s) (e.g., rotor/propeller, tilt mechanism, blade pitch mechanism, cooling systems, etc.). The preferred power/fuel source is a battery; however the system could reasonably be employed with any suitable power/fuel source. The aircraft can include auxiliary and/or redundant power sources (e.g., backup batteries, multiple batteries) or exclude redundant power sources. The aircraft can employ batteries with any suitable cell chemistries (e.g., Li-ion, nickel cadmium, etc.) in any suitable electrical architecture or configuration (e.g., multiple packs, bricks, modules, cells, etc.; in any combination of series and/or parallel architecture).

In a specific example, the system integrated into an electric tiltrotor aircraft including a plurality of tiltable rotor assemblies (e.g., six tiltable rotor assemblies). The electric tiltrotor aircraft can operate as a fixed wing aircraft, a rotary-wing aircraft, and in any liminal configuration between a fixed and rotary wing state (e.g., wherein one or more of the plurality of tiltable rotor assemblies is oriented in a partially rotated state). The control system of the electric tiltrotor aircraft in this example can function to command and control the plurality of tiltable rotor assemblies within and/or between the fixed wing arrangement and the rotary-wing arrangement.

The term “substantially” as utilized herein can mean: exactly, approximately, within a predetermined threshold or tolerance, and/or have any other suitable meaning.

Alternative embodiments implement the above methods and/or processing modules m non-transitory computer-readable media, storing computer-readable instructions. The instructions can be executed by computer-executable components integrated with the computer-readable medium and/or processing system. The computer-readable medium may include any suitable computer readable media such as RAMs, ROMs, flash memory, EEPROMs, optical devices (CD or DVD), hard drives, floppy drives, non-transitory computer readable media, or any suitable device. The computer-executable component can include a computing system and/or processing system (e.g., including one or more collocated or distributed, remote or local processors) connected to the non-transitory computer-readable medium, such as CPUs, GPUs, TPUS, microprocessors, or ASICs, but the instructions can alternatively or additionally be executed by any suitable dedicated hardware device.

Embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

As a person skilled in the art will recognize from the previous detailed description and from the figures and claims, modifications and changes can be made to the examples of the invention without departing from the scope of this invention defined in the following claims.

What is claimed is:

1. A half-bridge package comprising:
a first switch and a first lead coupled to the first switch; and
a second switch and a second lead coupled to the second switch,
wherein the first lead and the second lead are adjacent to one another.

2. The half-bridge package of claim 1, wherein the first switch and the second switch are located adjacent to each other in the half-bridge package, the second lead passing over the first switch.

3. The half-bridge package of claim 1, wherein the first and second leads are inverter power leads.

4. The half-bridge package of claim 1, wherein at least one of the first switch and the second switch are formed on a die, the half-bridge package further comprising a thermistor mounted to the die.

5. The half-bridge package of claim 4, wherein the thermistor is sintered to the die.

6. The half-bridge package of claim 4, further comprising a thermistor lead mounted to the thermistor.

7. The half-bridge package of claim 5, further comprising a thermistor lead mounted to the thermistor.

8. A power inverter comprising, a plurality of interconnected half-bridges, each half-bridge comprising:
a first switch and a first lead coupled to the first switch; and
a second switch and a second lead coupled to the second switch,
wherein the first lead and the second lead are adjacent to one another.

9. The power inverter of claim 8, wherein the first switch and the second switch in each half-bridge package are located adjacent to each other in each half-bridge package, the second lead passing over the first switch.

10. The power inverter of claim 8, wherein the first and second leads of each half-bridge package are inverter power leads.

11. The power inverter of claim 8, wherein at least one of the first switch and the second switch in each half-bridge package are formed on a die, each half-bridge package further comprising a thermistor mounted to the die.

12. The power inverter of claim 11, wherein the thermistor in each half-bridge package is sintered to the die in that half-bridge package.

13. The power inverter of claim 12, wherein each half-bridge package comprises a thermistor lead mounted to the thermistor in that half-bridge package.

14. The power inverter of claim 11, wherein each half-bridge package comprises a thermistor lead mounted to the thermistor in that half-bridge package.

15. A method of making a half-bridge package, comprising:
coupling a first lead to a first switch; and
coupling a second lead to a second switch such that the second lead is adjacent to the first lead.

16. The method of claim 15, wherein the first switch and the second switch are located adjacent to each other in the half-bridge package, the second lead passing over the first switch.

17. The method of claim 15, further comprising:
forming at least one of the first switch and the second switch on a die; and
mounting a thermistor to the die.

18. The method of claim 17, wherein mounting the thermistor to the die comprises sintering the thermistor to the die.

19. The method of claim 17, further comprising:
mounting a thermistor lead onto the thermistor.

20. The method of claim 18, further comprising:
mounting a thermistor lead onto the thermistor.
